(19) United States
(12) Patent Application Publication
(10) Pub. No.: US 2020/0194363 A1
(43) Pub. Date: Jun. 18, 2020

(54) ARRAY SUBSTRATE AND MANUFACTURING METHOD THEREFOR, DISPLAY DEVICE AND MANUFACTURING METHOD THEREFOR

(71) Applicant: BOE TECHNOLOGY GROUP CO., LTD., Beijing (CN)

(72) Inventors: Liqiang CHEN, Beijing (CN); Hongli WANG, Beijing (CN); Yanli WANG, Beijing (CN); Youwei WANG, Beijing (CN); Jianwei LI, Beijing (CN); Paoming TSAI, Beijing (CN)

(21) Appl. No.: 16/642,615

(22) PCT Filed: Oct. 12, 2018
(86) PCT No.: PCT/CN2018/109977

§ 371 Date: Feb. 27, 2020

(30) Foreign Application Priority Data
Oct. 13, 2017 (CN) 201710954432.X

(51) Int. Cl. H01L 23/498; H01L 23/00; H01L 21/48

(52) U.S. Cl. CPC H01L 23/49838; H01L 24/16; H01L 23/49811; H01L 23/4985; H01L 2224/81005; H01L 21/4857; H01L 24/81; H01L 2224/16227; H01L 21/4853

(57) ABSTRACT

A manufacturing method of an array substrate includes forming a plurality of bonding pads in a bonding region of a base substrate, and forming at least one insulating support part at at least one position where the plurality of bonding pads are not provided in the bonding region of the base substrate.

### CROSS-REFERENCE TO RELATED APPLICATIONS

This application is a national phase entry under 35 USC 371 of International Patent Application No, PCT/CN2018/109977 filed on Oct. 12, 2018, which claims priority to Chinese Patent Application No. 201710954432. X, filed with the Chinese Patent Office on Oct. 13, 2017, titled “ARRAY SUBSTRATE AND MANUFACTURING METHOD THEREFOR, AND FLEXIBLE DISPLAY DEVICE”, which are incorporated herein by reference in their entirety.

### TECHNICAL FIELD

The present disclosure relates to the field of flexible display technologies, and in particular, to an array substrate and a manufacturing method therefor, and a display device and a manufacturing method therefor.

### BACKGROUND

With the development of display technologies, flexible display panels are widely used in more and more electronic devices due to their characteristics such as lightness and thinness, and good impact resistance. Display devices using flexible display panels include liquid crystal display devices, organic electroluminescent display devices, and electrophoretic display devices. For example, flexible display devices can be applied to electronic equipment such as smart cards, portable computers, and electronic paper. During manufacturing a flexible display device, a flexible substrate is generally disposed on a glass substrate, and then various layer structures required for display are manufactured on the flexible substrate to form a flexible display panel. Such a process may be compatible with equipment for manufacturing related display panels. After the flexible display panel is manufactured, the flexible substrate needs to be separated from the glass substrate, and then a back film is attached to a back surface of the flexible substrate (i.e., a surface on which various layer structures required for display are not manufactured) to flatten the flexible substrate. Next the flexible substrate is cut, and finally processes such as bonding an integrated circuit (IC) are performed on the flexible substrate.

### SUMMARY

In one aspect, embodiments of the present disclosure provide a manufacturing method of an array substrate. The manufacturing method includes forming a plurality of bonding pads in a bonding region of a base substrate, and forming at least one insulating support part at at least one position where the plurality of bonding pads are not provided in the bonding region of the base substrate. The bonding region is a region covered by an integrated circuit (IC) after the IC is bonded, and the at least one insulating support part are used to maintain a gap between the array substrate and an IC to be bonded.

In some embodiments of the present disclosure, a distance from a surface of the at least one insulating support part facing away from the base substrate to a surface of the base substrate facing the plurality of bonding pads is greater than a distance from a surface of at least one bonding pad facing away from the base substrate to the surface of the base substrate facing the plurality of bonding pads.

In some embodiments of the present disclosure, a difference between the distance from the surface of the insulating support part to the surface of the base substrate facing the plurality of bonding pads and the distance from the surface of the bonding pad to the surface of the base substrate facing the plurality of bonding pads is less than or equal to a thickness of an IC bump.

In some embodiments of the present disclosure, the manufacturing method further includes forming at least one insulating layer in a non-bonding region of the base substrate. At least one part of an insulating support part is formed in a same layer as an insulating layer.

In some embodiments of the present disclosure, an insulating support part includes a multilayer structure.

In some embodiments of the present disclosure, forming at least one insulating layer in the non-bonding region of the base substrate includes sequentially forming a planarization layer body, a pixel defining pattern, and a spacer pattern in the non-bonding region of the base substrate in a direction perpendicular to a surface of the base substrate facing the plurality of bonding pads. Forming one of the at least one insulating support part includes sequentially forming a first sub-layer, a second sub-layer, and a third sub-layer in the direction perpendicular to the surface of the base substrate facing the plurality of bonding pads. The first sub-layer is formed in a same layer as the planarization layer body, the second sub-layer is formed in a same layer as the pixel defining pattern, and the third sub-layer is formed in a same layer as the spacer pattern.

In some embodiments of the present disclosure, forming the at least one insulating layer and forming one of the at least one insulating support part includes: forming a first insulating film above the base substrate, and performing a patterning process on the first insulating film to form the planarization layer body in the non-bonding region of the base substrate and the first sub-layer in the bonding region; forming a second insulating film above the base substrate above which the planarization layer body and the first sub-layer have been formed, and performing a patterning process on the second insulating film to form the pixel defining pattern in the non-bonding region and the second sub-layer in the bonding region; and forming a third insulating film above the base substrate above which the pixel defining pattern and the second sub-layer have been formed, and performing a patterning process on the third insulating film to form the spacer pattern in the non-bonding region and the third sub-layer in the bonding region.

In some embodiments of the present disclosure, the manufacturing method further includes forming an organic filling pattern in a region between the non-bonding region of the base substrate and the bonding region of the base substrate before forming the planarization layer body. Forming one of the at least one insulating support part further includes forming a fourth sub-layer before forming the first sub-layer. The fourth sub-layer is formed in a same layer as the organic filling pattern.

In some embodiments of the present disclosure, forming the at least one insulating layer and forming one of the at least one insulating support part includes: forming a forth insulating film above the base substrate, and performing a patterning process on the forth insulating film to form the organic filling pattern in the region between the non-bonding region of the base substrate and the bonding region of the base substrate and the forth sub-layer in the bonding region; forming a first insulating film above the base substrate above which the organic filling pattern and the forth sub-layer have been formed, and performing a patterning process on the first insulating film to form the planarization layer body in the non-bonding region of the base substrate and the first sub-layer in the bonding region; forming a second insulating film above the base substrate above which the planarization layer body and the first sub-layer have been formed, and performing a patterning process on the second insulating film to form the pixel defining pattern in the non-bonding region and the second sub-layer in the bonding region; and forming a third insulating film above the base substrate above which the pixel defining pattern and the second sub-layer have been formed, and performing a patterning process on the third insulating film to form the spacer pattern in the non-bonding region and the third sub-layer in the bonding region.

In some embodiments of the present disclosure, a multilayer structure includes at least two sub-layers, and orthographic projections of the at least two sub-layers on the base substrate at least partially overlap to form a stacked structure.

In some embodiments of the present disclosure, the multilayer structure includes at least two sub-layers, and shapes of the at least two sub-layers are the same.

In some embodiments of the present disclosure, the base substrate is a flexible base substrate.

In another aspect, embodiments of the present disclosure provide a manufacturing method of a display device. The manufacturing method includes: forming an array substrate on a rigid support substrate by the manufacturing method as described above; peeling the array substrate from the rigid support substrate; attaching a protective back film on a side of the flexible substrate facing away from the plurality of bonding pads; providing at least one IC, each of which includes a plurality of IC bumps; and bonding each IC bump to a corresponding bonding pad. The base substrate in the array substrate is a flexible base substrate.

In yet another aspect, embodiments of the present disclosure provide an array substrate. The array substrate includes: a base substrate having a bonding region, a plurality of bonding pads in the bonding region of the base substrate, and at least one insulating support part disposed at at least one position where the plurality of bonding pads are not provided in the bonding region. The bonding region is a region covered by an integrated circuit (IC) after the IC is bonded, and the at least one insulating support part is configured to maintain a gap between the array substrate and an IC to be bonded.

In some embodiments of the present disclosure, a distance from an surface of the at least one insulating support part facing away from the base substrate to a surface of the base substrate facing the plurality of bonding pads is greater than a distance from an surface of at least one bonding pad facing away from the base substrate to the surface of the base substrate facing the plurality of bonding pads.

In some embodiments of the present disclosure, the plurality of bonding pads include a first bonding pad group and a second bonding pad group, and the at least one insulating support part includes at least one insulating support part group. The first bonding pad group includes at least one input bonding pad, and the second bonding pad group includes at least one output bonding pad, and the first bonding pad group, the second bonding pad group and the at least one insulating support part group are spaced apart from each other.

In some embodiments of the present disclosure, the at least one insulating support part group is disposed between the first bonding pad group and the second bonding pad group.

In some embodiments of the present disclosure, at least one insulating support part group includes a plurality of insulating support part groups. One or more insulating support part groups are disposed at a side of the first bonding pad group facing away from the second bonding pad group, or one or more insulating support part groups are disposed at a side of the second bonding pad group facing away from the first bonding pad group, or one or more insulating support part groups are disposed at the side of the first bonding pad group facing away from the second bonding pad group and one or more insulating support part groups are disposed at the side of the second bonding pad group facing away from the first bonding pad group.

In some embodiments of the present disclosure, the first bonding pad group includes at least one row of input bonding pads spaced apart from each other, the second bonding pad group includes at least one row of output bonding pads spaced apart from each other, and the at least one insulating support part group includes at least one row of insulating support parts spaced apart from each other. At least one row of input bonding pads, at least one row of output bonding pads and at least one row of insulating support parts are parallel to each other.

In some embodiments of the present disclosure, an area of a surface of an insulating support part facing away from the base substrate is less than an area of a surface of the insulating support part facing the base substrate.

In some embodiments of the present disclosure, the array substrate further includes at least one insulating layer disposed in a non-bonding region of the base substrate. At least one part of an insulating support part is formed in a same layer as an insulating layer.

In some embodiments of the present disclosure, the at least one insulating layer includes a planarization layer body, a pixel defining pattern and a spacer pattern, all of which are sequentially disposed above the base substrate in a direction perpendicular to a surface of the base substrate facing the plurality of bonding pads. One of the at least one insulating support part includes a first sub-layer, a second sub-layer and a third sub-layer, all of which are sequentially disposed above the base substrate in the direction perpendicular to the surface of the base substrate facing the plurality of bonding pads. The first sub-layer is disposed in a same layer as the planarization layer body, the second sub-layer is disposed in a same layer as the pixel defining pattern, and the third sub-layer is disposed in a same layer as the spacer pattern.

In some embodiments of the present disclosure, the array substrate further includes an organic filling pattern disposed between the planarization layer and the base substrate and located in a region between the non-bonding region and the bonding region. The insulating support part further includes a fourth sub-layer located between the first sub-layer and the base substrate. The fourth sub-layer is formed in a same layer as the organic filling pattern.

In yet another aspect, embodiments of the present disclosure provide a display device. The display device includes the array substrate as described above, and at least one IC. Each IC includes a plurality of IC bumps, and each IC bump is bonded to a corresponding bonding pad.

In some embodiments of the present disclosure, a difference between a distance from a surface of the at least one insulating support part facing away from the base substrate to a surface of the base substrate facing the plurality of bonding pads and a distance from a surface of at least one bonding pad facing away from the base substrate to the surface of the base substrate facing the plurality of bonding pads is less than or equal to a thickness of at least one IC bump.

### BRIEF DESCRIPTION OF THE DRAWINGS

FIG. 1 is a schematic diagram showing a structure of a flexible display device in which an integrated circuit (IC) is bonded by means of chip on plastic (COP), according to exemplary embodiments of the present disclosure;

FIG. 2A is a schematic diagram showing various defects that occur in a case where an IC is directly bonded in a flexible display device in the related art;

FIG. 2B is a schematic diagram specifically showing defects that occur in a case where an IC is directly bonded to a flexible display panel in the related art;

FIG. 3 is a schematic diagram showing structures in a bonding region of an array substrate, according to some embodiments of the present disclosure;

FIG. 4 is a schematic diagram showing a process of bonding an IC to the bonding region of the array substrate shown in FIG. 3:

FIG. 5 is a schematic diagram showing a structural change of an array substrate before and after crimping the IC, according to some embodiments of the present disclosure;

FIG. 6 is a schematic structural diagram of a cross-section in an A-A′ direction in FIG. 3;

FIG. 7 is a schematic diagram showing structures in a bonding region of another array substrate, according to some embodiments of the present disclosure;

FIG. 8 is a schematic diagram showing a structure of the array substrate shown in FIG. 3 including two groups of insulating support parts located between input bonding pads and output bonding pads;

FIG. 9 is a schematic diagram showing a structure of an insulating support part in the array substrate shown in FIG. 3;

FIG. 10 is a schematic diagram showing a structure of the array substrate including an organic filling layer, according to some embodiments of the present disclosure;

FIG. 11 is a schematic diagram showing another structure of an insulating support part in the array substrate shown in FIG. 3;

FIG. 12 is a schematic diagram showing a process of forming insulating support parts by an inkjet printing method, according to some embodiments of the present disclosure;

FIG. 13 is a schematic diagram showing a structure of a flexible display device, according to some embodiments of the present disclosure;

FIG. 14 is a flow diagram of a manufacturing method of an array substrate, according to some embodiments of the present disclosure; and

FIG. 15 is a flow diagram of another manufacturing method of an array substrate, according to some embodiments of the present disclosure.

### DETAILED DESCRIPTION

In order to make the objectives, technical solutions and advantages in embodiments of the present disclosure clearer, the technical solutions in the embodiments of the present disclosure will be described clearly and completely with reference to the accompanying drawings in the embodiments of the present disclosure. Obviously, the described embodiments are merely some but not all of embodiments of the present disclosure. All other embodiments made on the basis of the embodiments of the present disclosure by a person of ordinary skill in the art without paying any creative effort shall be included in the protection scope of the present disclosure.

In an exemplary embodiment of the present disclosure, in a manufacturing process of a related display device (e.g., a flexible display device), an integrated circuit (IC) is generally bonded by using a manner of chip on film (COF). That is, the IC is bonded to an array substrate of a display panel (e.g., a flexible display panel) by utilizing the COF. Since the COF is made of a soft material, circuits in the array substrate will not be broken during crimping the COF. However, since the cost of the COF is high and circuit traces manufactured on the COF cannot be very thin, bonding by the manner of COF is difficult to be applied to a high-resolution display device.

It is a development direction in the future to bond the IC by using a manner of chip on plastic (COP) (i.e., by directly bonding a chip on a flexible substrate).

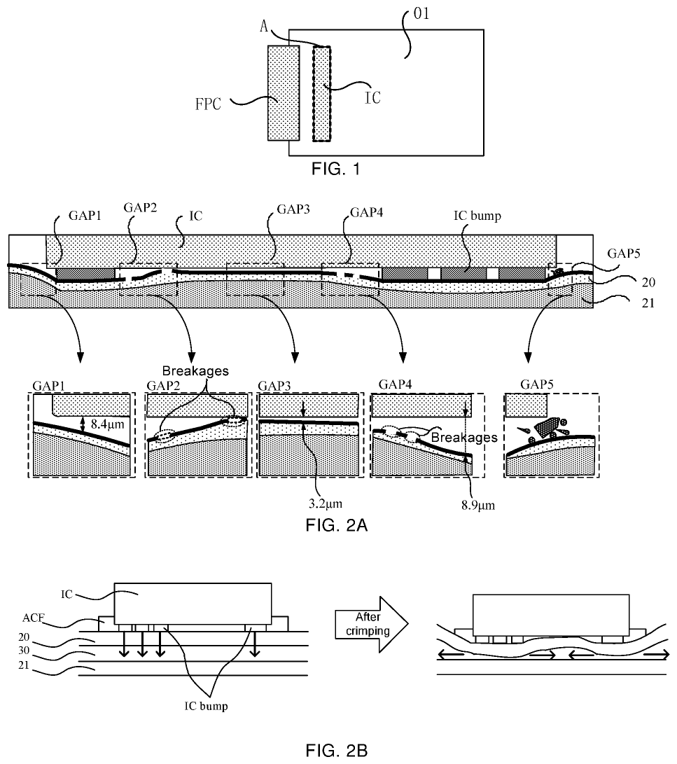

As shown in FIG. 1, bonding by the manner of COP includes: directly bonding the IC (marked as “IC” in FIG. 1) in the bonding region A of the display panel 01 (e.g., a flexible display panel), and then attaching a flexible printed circuit (marked as “FPC” in FIG. 1) to the display panel. A region of the flexible display panel 01 covered by the IC is the bonding region A. However, in a case where the IC is directly crimped onto the flexible display panel 01 by the manner of COP, as shown in FIG. 2A, there exist the following defects:

(1) Due to a high hardness of the IC, in a case where the IC is directly crimped (the crimping manner is, for example, hot pressing) onto the flexible display panel, regions of a back film 21 in the flexible display panel corresponding to IC bumps (marked as “IC bump” in FIG. 2A) will sag, and then regions of a flexible substrate 20 corresponding to the sagged regions of the back film 21 will also sag. Thereby, segment differences are formed between a region of the flexible substrate 20 which sags and the other regions of the flexible substrate 20.

In this way, wirings located at peripheries of the sagged positions on the flexible substrate 20 are prone to breakage. For example, as shown by the GAP 2 and GAP 4 in FIG. 2A, wire breakages occur at a position of the flexible substrate 20 where there is a segment difference.

FIG. 2B is a schematic diagram showing a sagging process of the back film 21 which is caused by crimping the IC. As will be seen from FIG. 2B, since the back film 21 and the flexible substrate 20 are generally adhered together by pressure sensitive adhesive 30, in a case where the IC is crimped onto the flexible substrate 20, portions of the pressure sensitive adhesive 30 corresponding to the IC bumps (marked as “IC bump” in FIG. 2B) is pressed and then moves to a region of the flexible substrate which not corresponds to the IC bumps, thereby causing the flexible substrate 20 to have a large degree of bending. The pressing direction is shown by the arrows in the left part of FIG. 2B.

(2) In a case where the IC is bonded to the flexible display panel 01 by the manner of COP, the IC needs to be bonded to the flexible display panel through an anisotropic conductive film (ACF). Conductive particles are dispersed in the ACF, and a phenomenon of aggregation of conductive particles (for example, shown by GAP 5 in FIG. 2A) may occur at the sagged positions, which may increase the risk of short circuits in the wirings of flexible display panel.

(3) During bonding the IC, an IC bump is connected to a bonding pad in the flexible display panel, so that signals in the IC may be transmitted to the wirings in the flexible display panel. In a case where portions of the IC other than the IC bumps are in contact with the wirings on the flexible substrate 20, a short circuit may occur. In an example where a preset distance between the flexible substrate 20 and the IC is 10 μm, in a case where the IC is crimped onto the flexible display panel by using, for example, a hot pressing manner, the pressure sensitive adhesive on the back film in the flexible display panel corresponding to the IC bumps will flow to the peripheries of the sagged positions of the flexible substrate 20, as shown by GAP 1, GAP 3, and GAP 4 in FIG. 2A. Therefore, regions of the flexible substrate 20 corresponding to peripheral regions of the IC bumps are raised, which cause that distances between the flexible substrate 20 and portions of the IC other than the IC bumps are decreased to, for example, 8.4 μm, 3.2 μm, and 8.9 μm respectively.

In this way, a risk of short circuits between the signals in the IC and the wirings in the flexible display panel may increase. For example, as shown by GAP 2 and GAP 3 in FIG. 2A, the flexible substrate 20 is almost in contact with the middle portion of the IC, thereby easily causing a short circuit.

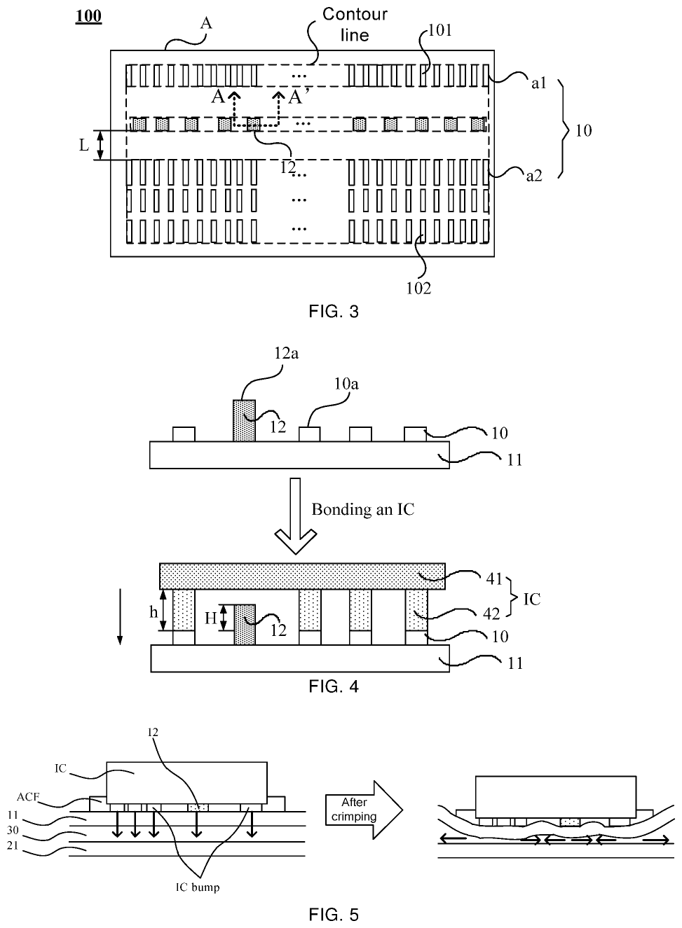

In an aspect, some embodiments of the present disclosure provide an array substrate 100. FIGS. 3 and 4 each show a structure of the array substrate 100 in a bonding region A. The array substrate 100 includes a base substrate 11, and a plurality of bonding pads 10 disposed in the bonding region A of the base substrate 11. As shown in FIG. 4, the bonding pad 10 is configured to bond an IC bump 42. The bonding region is a region covered by the IC after the IC is bonded. The array substrate 100 further includes insulating support parts 12 disposed at positions where the bonding pads 10 are not provided in the bonding region A. The insulating support parts 12 are configured to maintain a gap between the array substrate and an IC to be bonded.

The base substrate 11 may be a flexible base substrate or a rigid base substrate. The flexible base substrate may be a substrate with good flexibility, such as a plastic substrate. The array substrate including the flexible base substrate is bendable or foldable, and thus functionality of a display device including the array substrate may be expanded. The rigid base substrate may be, for example, a glass substrate.

The bonding region A of the base substrate 11 in the array substrate 100 refers to a preset region of the base substrate which is used to bond the IC, that is, a region of the base substrate 11 covered by the bonded IC is used as the bonding region A. In general, an area of a region covered by the IC bonded to the base substrate 11 of the array substrate 100, i.e., an area of the bonding region A, is greater than an area of a region formed by an outermost contour line of a plurality of bonding pads 10 as shown in FIG. 3.

A structure of the IC is generally as shown in FIG. 4, and the IC includes an IC body 41 and IC bumps 42. A positional relationship between the IC body 41 and the IC bumps 42 and the number of the IC body and the IC bumps 42 that are shown in FIG. 4 are merely for illustration, which is not a limitation on the specific structure of the IC.

In addition, one or more ICs may be bonded to one array substrate 100. In this case, structures in a region of the array substrate 100 covered by each IC may be structures provided by some embodiments of the present disclosure.

The term “insulating” in the insulating support part 12 means that it will not destroy an original electrical connection relationship between the IC and corresponding structures in the array substrate. Therefore, at least an outermost layer of the insulating support part 12 is insulating. That is, all materials for forming the insulating support part 12 may be insulating materials; or, the outermost layer of the insulating support part 12 may be made of an insulating material and an interior of the insulating support part may contain non-insulating materials (e.g., semiconductor materials, or metal materials, which may shape the outermost layer of the insulating support part 12).

The insulating support parts 12 may be manufactured separately, that is, a step of manufacturing the insulating support parts 12 is added on the basis of steps of manufacturing a related array substrate. Or, the insulating support parts 12 may also be simultaneously manufactured with one or more layers in a structure in the array substrate located outside the bonding region A of the base substrate. In this way, by changing pattern(s) of one or more layers in the related array substrate, the insulating support parts 12 located in the bonding region of the base substrate may be formed without increasing the steps of manufacturing the array substrate.

The array substrate 100 provided by some embodiments of the present disclosure further includes insulating support part(s) 12 that are located at position(s) where the bonding pads 10 are not provided in the bonding region A of the base substrate 11, and as shown in FIG. 5, the insulating support part(s) 12 are able to play a role in preventing an occurrence of bending in a region where the bonding pads 10 are not provided in the bonding region A. Therefore, the pressed portion of the pressure sensitive adhesive 30 disperses (as shown by the arrows in the right part of FIG. 5) due to the insulating support part(s). Since the pressure sensitive adhesive 30 may be prevented from gathering after being pressed, a degree of bending of the entire array substrate may be reduced, thereby maintaining the gap between the IC and the array substrate.

In addition, since the insulating support part 12 is insulating, the wirings on the warped portion of the base substrate 11 may also be prevented from being in direct contact with the circuit traces on the IC, thereby reducing the risk of short circuits between the wirings in the array substrate 100 and the circuit traces on the IC. The insulating support part 12 may also reduce the probability of aggregation of the conductive particles in the ACF occurring at portions of the ACF corresponding to the IC bumps 42, thereby reducing the risk of short circuits due to the aggregation of the conductive particles in the ACF.

In some embodiments of the present disclosure, as shown in FIG. 4, a distance from an upper surface 12a of the insulating support part 12 facing away from the base substrate 11 to a surface of the base substrate 11 facing the plurality of bonding pads is greater than a distance from an upper surface 10a of the bonding pad 10 facing away from the base substrate 11 to the surface of the base substrate 11 facing the plurality of bonding pads.

In the following embodiments, an example where the base substrate 11 is a flexible base substrate 11 is taken for illustration.

That is, the upper surface 12a of the insulating support part 12 facing away from the flexible base substrate 11 is higher than a plane where the upper surface 10a of the bonding pad 10 facing away from the base substrate 11 is located.

Herein, the relative positions of “upper” and “lower” in some embodiments of the present disclosure may be referred to FIG. 4. A surface of the insulating support part 12 facing away from the flexible base substrate 11 is regarded as the upper surface 12a of the insulating support part 12, and a surface of the bonding pad 10 facing away from the flexible base substrate 11 is regarded as the upper surface 10a of the bonding pad 10.

Since the upper surface 12a of the insulating support part 12 is higher than the plane where the upper surface 10a of the bonding pad 10 is located, that is, a part of the insulating support part 12 is higher than the bonding pad 10, the insulating support part 12, a part of which is higher than the bonding pad 10, may play a supporting role between the IC body 41 and the flexible base substrate 11 during bonding the IC to the array substrate 100.

Some embodiments of the present disclosure do not limit a positional relationship between a lower surface of the insulating support part 12 and a lower surface of the bonding pad 10, as long as the upper surface 12a of the insulating support part 12 is higher than the plane where the upper surface 10a of the bonding pad 10 is located.

For example, in a case where the insulating support parts 12 are separately manufactured, that is, a step of manufacturing the insulating support parts 12 is added on the basis of the steps of manufacturing the related array substrate, the lower surface of the insulating support part 12 and the lower surface of the bonding pad 10 may be in a same plane.

For another example, in a case where the insulating support parts 12 is simultaneously manufactured with one or more layers in a structure in the array substrate located outside the bonding region A of the flexible base substrate, the lower surface of the insulating support part 12 and the lower surface of the bonding pad 10 may be in different planes.

The insulating support part 12 is provided in the flexible base substrate 11 of the array substrate 100 without affecting the bonding between the IC and the bonding pads. In a direction perpendicular to a surface of the flexible base substrate 11, a height of the insulating support part 12 may be adjusted according to the type of the IC.

For example, as shown in FIG. 4, in a case where a lower surface of the IC bump 42 (i.e., a surface of the IC bump 42 facing the IC body 41) and an upper surface of the IC body 41 (i.e., a surface of the IC body 41 facing the bonding pads 10) are in a same plane, in order not to affect the bonding between the IC and the bonding pads 10, in the direction perpendicular to the surface of the flexible base substrate 11 (as shown by the one-way arrow in FIG. 4), a difference between a distance from the upper surface 12a of the insulating support part 12 to the surface of the flexible base substrate 11 and a distance from the upper surface 10a of the bonding pad 10 to the surface of the flexible base substrate 11 is less than or equal to a thickness of the IC bump of the IC to be bonded.

That is, a height H from the upper surface 12a of the insulating support part 12 to the plane where the upper surface 10a of the bonding pad 10 is located is less than or equal to a thickness h of the IC bump 42. In this way, in a case where the IC bump 42 is bonded to the bonding pad 10, it may be ensured that a middle portion of the IC body 41 will not be lifted up by the insulating support part 12, thereby not affecting the bonding effect of the IC.

Herein, within a range not exceeding a sum of a height of an IC bump and a height of a bonding pad, the height of the insulating support part 12 may be set as high as possible to provide a more stable support for the IC.

For example, the height H from the upper surface 12a of the insulating support part 12 to the plane where the upper surface 10a of the bonding pad 10 is located is equal to the thickness h of the IC bump 42. That is, in a case where the IC is bonded to the array substrate, the upper surface 12a of the insulating support part 12 can come into contact with the IC body 41. In this way, a support provided by the insulating support part 12 for the IC is firm.

Herein, in a case where the number of the insulating support parts is small, a planar size of each insulating support part may be set to be large to provide a sufficient support for the IC; and in a case where distances between the insulating support parts are small, that is, the insulating support parts are arranged proximate to each other, the planar size of each insulating support part may be set to be small.

The above arrangement manners are merely for illustration. The planar size of the insulating support part is not limited in the present disclosure. The planar size of the insulating support part may be flexibly adjusted according to an area of the bonding region A, the number of the insulating support parts, and an arrangement manner of the insulating support parts.

In the above array substrate provided by some embodiments of the present disclosure, the upper surface 12a of the insulating support part 12 is higher than the plane where the upper surface 10a of the bonding pad 10 is located. In this way, the insulating support part 12 may play a certain supporting role, so that a fixed distance is maintained between the IC and the peripheries of the regions of the flexible base substrate 11 corresponding to the IC bumps 42, and thus a gap between the IC and the array substrate is maintained. As a result, the wirings on the warped portion of the flexible base substrate 11 may be prevented from being in contact with the circuit traces on the IC, thereby reducing the risk of short circuits between the wirings in the array substrate 100 and the circuit traces on the IC.

In addition, since the insulating support part 12 may keep a fixed distance between the IC and the peripheries of the regions of the flexible base substrate 11 corresponding to the IC bumps 42, it is possible to reduce a segment difference between the region of the flexible base substrate 11 corresponding to the IC bump 42 and the periphery thereof. In this way, after an IC bonding process is completed, a surface of the flexible base substrate 11 is relatively flat. As a result, in one aspect, the probability of wire breakages on the flexible base substrate 11 may be reduced; in another aspect, the probability of aggregation of conductive particles in the ACF occurring at portions of the ACF corresponding to the IC bumps 42 may be reduced, thereby reducing the risk of short circuits due to the aggregation of the conductive particles in the ACF.

A particle diameter of a single conductive particle in the ACF is generally approximately 5 μm. In a case where the number of aggregated conductive particles is large, for example, approximately 10 conductive particles are gathered, a short circuit occurs between the bonding pad 10 and a wire in a region adjacent to a position where the bonding pad 10 of the flexible base substrate 11 is located.

As shown in FIG. 3, in a case where a distance L between a side of a group of the insulating support parts 12 facing a second bonding pad group a2 and a side of the second bonding pad group a2 facing the group of the insulating support parts 12 is less than 50 μm (i.e., a sum of the particle diameters of approximately 10 conductive particles), the conductive particles gathered between the insulating support part 12 and the bonding pad 10 may increase the risk of a short circuit between the wirings in the array substrate and the circuit traces on the IC. Therefore, considering the properties of the ACF, in a direction perpendicular to the row direction of the bonding pads, the distance L between the side of the group of the insulating support parts 12 facing a second bonding pad group a2 and the side of the second bonding pad group a2 facing the group of the insulating support parts 12 is greater than or equal to 50 μm.

Herein, the “distance L” refers to a distance between a side of the insulating support part 12 proximate to the bonding pad 10 and a side of the bonding pad 10 proximate to the insulating support part 12 in the surface of the flexible base substrate 11.

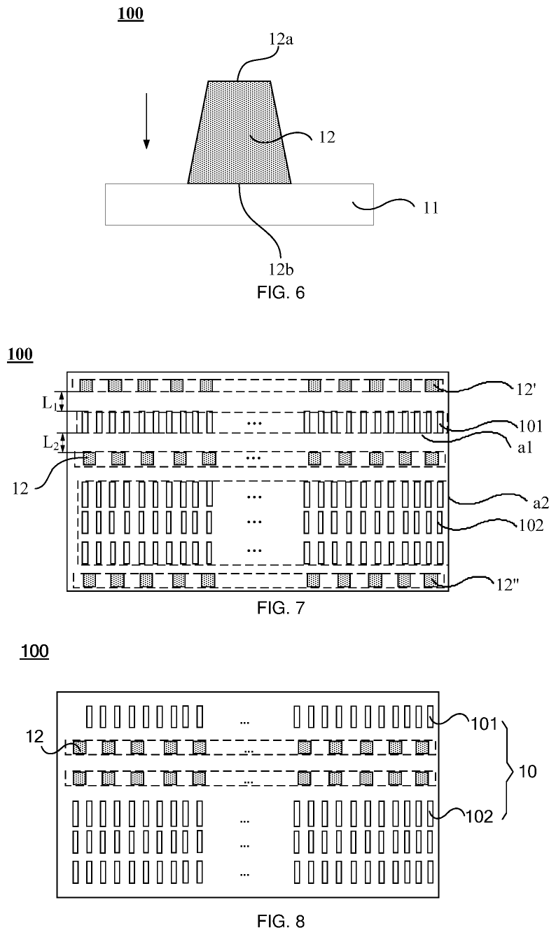

In some embodiments of the present disclosure, as shown in FIG. 6, an area of the upper surface 12a of the insulating support part 12 facing away from the flexible base substrate 11 is less than an area of the lower surface 12b of the insulating support part 12 facing the flexible base substrate 11.

That is, in the direction perpendicular to the surface of the flexible base substrate 11 (as shown by the one-way arrow in FIG. 6), a cross section of the insulating support part 12 has a trapezoidal shape, and a length of an upper side of the cross section is smaller than a length of a lower side thereof. In this way, in a case where the IC is crimped onto the array substrate and the pressure is large, since the insulating support part 12 itself has a structure in which an upper portion is smaller than a lower portion, the lower portion of the insulating support part 12 is able to provide a more stable support for its upper portion, thereby providing a more stable support for the IC.

In some embodiments of the present disclosure, the IC bumps 42 generally include input bumps spaced apart from each other and output bumps spaced apart from each other. The input bumps are configured to transmit a power of an external power supply into the IC, and the output bumps are configured to transmit IC signals to the array substrate bonded with the IC.

Correspondingly, as shown in FIG. 3, the bonding pads 10 generally include input bonding pads 101 spaced apart from each other and output bonding pads 102 spaced apart from each other. During bonding the IC, the input bonding pads 101 correspond to the input bumps, and the output bonding pads 102 correspond to the output bumps.

Herein, in some drawings provided according to some embodiments of the present disclosure, it should be understood by those skilled in the art that the number and arrangement form of the bonding pads 10 are only for illustration, and the number and arrangement form of the bonding pads 10 are not limited. In a case where the number and arrangement form of the IC bumps 42 are changed, the number and arrangement form of the bonding pads 10 are also changed accordingly during manufacturing the array substrate,

In the array substrate 100 provided by some embodiments of the present disclosure, as shown in FIG. 3, the bonding pads 10 include a first bonding pad group a1 and a second bonding pad group a2 that are spaced apart from each other. The first bonding pad group a1 includes at least one input bonding pad 101, and the second bonding pad group a2 includes at least one output bonding pad 102. Insulating support part(s) 12 are divided into at least one group. Insulating support part(s) 12 in a same group are disposed at a side of the first bonding pad group a1 and at a side of the second bonding pad group a2. A distances between each insulating support part 12 in each insulating support part group and a boundary of the second bonding pad group a2 is equal.

Here, since a distance between the first bonding pad group a1 and the second bonding pad group a2 is a fixed value, a distance between each insulating support part 12 in each insulating support part group and a boundary of the first bonding pad group a1 is also equal.

In a case where “insulating support part(s) 12 in a same group are disposed at a side of the first bonding pad group a1 and at a side of the second bonding pad group a2”, there are three exemplary arrangements of a group of the insulating support part(s) 12, the first bonding pad group a1 and the second bonding pad group a2.

For example, as shown in FIG. 3, a group of insulating support parts 12 is disposed between the first bonding pad group a1 and the second bonding pad group a2.

Or, as shown in FIG. 7, a group of insulating support parts 12′ is disposed at a side of the first bonding pad group a1 facing away from the second bonding pad group a2.

Or, as shown in FIG. 7, a group of insulating support parts 12″ is disposed at a side of the second bonding pad group a2 facing away from the first bonding pad group a1.

Herein, in FIG. 7, an example where a distance L1 between a side of the group of the insulating support parts 12′ facing the first bonding pad group a1 and a side of the first bonding pad group a1 facing the group of the insulating support parts 12′ is equal to a distance L2 between a side of the group of the insulating support parts 12 facing the first bonding pad group a1 and a side of the first bonding pad group a1 facing the group of the insulating support parts 12 is taken for illustration. L1 and L2 may or may not be equal.

According to the arrangement manner that “insulating support part(s) 12 in a same group are disposed at a side of the first bonding pad group a1 and at a side of the second bonding pad group a2”, the insulating support parts 12′ are in a same group, and the insulating support parts 12 are in a same group.

In some embodiments of the present disclosure, as shown in FIG. 3 or FIG. 7, the first bonding pad group a1 includes at least one row of input bonding pads 101 spaced apart from each other, the second bonding pad group a2 includes at least one row of output bonding pads 102 spaced apart from each other, and each insulating support part group includes at least one row of insulating support parts 12 spaced apart from each other. At least one row of input bonding pads 101 spaced apart from each other, at least one row of output bonding pads 102 spaced apart from each other, and at least one row of insulating support parts 12 spaced apart from each other are parallel to each other. In this way, terminal structures arranged in rows in the bonding region are more neatly arranged, which is convenient for IC bonding and supporting the IC.

In some embodiments of the present disclosure, each group of insulating support part(s) 12 may, as shown in FIG. 3 or FIG. 7, include a plurality of insulating support columns spaced apart from each other; or, each group of insulating support part(s) 12 includes an insulating support strip.

In a case where the insulating support parts 12 include a plurality of insulating support columns spaced apart from each other, the shapes and the number of the insulating support columns are not limited in some embodiments of the present disclosure, as long as the insulating support part 12 is able to play a certain supporting role between the flexible substrate 11 and the IC body 41 during bonding the IC.

For example, a shape of an upper surface of the insulating support column may be a circle or a rectangle. In some drawings provided according to some embodiments of the present disclosure, an example where the shape of the upper surface of the insulating support column is a rectangle is taken for illustration.

In some embodiments of the present disclosure, in a case where a planar size of the insulating support column is less than 50 μm, the supporting effect of a single insulating support column is poor, and it is difficult to maintain a fixed distance between the flexible base substrate 11 and the IC body 41 during bonding the IC, In a case where the planar size of the insulating support column is greater than 200 μm, since an area of the bonding region A is small, it is difficult to form an insulating support column having a planar size of 200 μm between the input bonding pad 101 and the output bonding pad 102. Therefore, the planar size of the insulating support column is in a range from 50 μm to 200 μm. The number of insulating support columns may be adjusted according to the size of the IC.

Herein, in a case where the shape of the upper surface of the insulating support column is a rectangle, the planar size refers to a length or width of the rectangle. In a case where the shape of the upper surface of the insulating support column is a circle, the planar size refers to a diameter of the circle.

In some embodiments of the present disclosure, as shown in FIG. 3, the insulating support parts 12 are disposed between the input bonding pads 101 and the output bonding pads 102.

In this case, due to the supporting function of the insulating support parts 12, a fixed distance is maintained between the flexible base substrate 11 and the middle portion of the IC body 41, thereby reducing the probability that the wirings on the flexible base substrate 11 are in contact with the circuit traces on the IC, and further reducing the risk of short circuits.

For example, as shown in FIG. 8, the array substrate 100 includes at least two groups of insulating support parts 12 which are disposed between the input bonding pads 101 and the output bonding pads 102, and each group of insulating support parts includes a plurality of insulating support parts 12 spaced apart from each other in one row to improve the overall supporting effect of the insulating support parts 12.

In some embodiments of the present disclosure, the insulating support part(s) 12 are disposed at a side of the input bonding pad 101 facing away from the output bonding pad 102, or disposed at a side of the output bonding pad 102 facing away from the input bonding pad 101.

In this case, due to the supporting function of the insulating support parts 12, a fixed distance may be maintained between the flexible base substrate 11 and an edge portion of the IC body 41, thereby reducing the probability that the wirings on the warped portions of the flexible base substrate 11 are in contact with the circuit traces on the IC, and further reducing the risk of short circuits.

In some embodiments of the present disclosure, as shown in FIG. 7, the insulating support parts 12 are disposed between the first bonding pad group a1 composed of a plurality of input bonding pads 101 and the second bonding pad group a2 composed of a plurality of output bonding pads 102, the insulating support parts 12′ are disposed at a side of the first bonding pad group a1 composed of the plurality of input bonding pads 101 facing away from the second bonding pad group a2 composed of the plurality of output bonding pads 102, and the insulating support parts 12″ are disposed at a side of the second bonding pad group a2 composed of the plurality of output bonding pads 102 facing away from the first bonding pad group a1 composed of the plurality of input bonding pads 101.

In this way, during bonding the IC, the insulating support parts 12 can maintain a fixed distance between portions of the IC body 41 which are not corresponding to the IC bumps 42 and the warped portions of the flexible base substrate 11. Therefore, it is possible to reduce the probability that the wirings on the warped portion of the flexible base substrate 11 are in contact with the circuit traces on the IC body 41, and reduce the risk of short circuits.

In some embodiments of the present disclosure, in order to simplify the manufacturing process of the array substrate, the insulating support parts 12 may be formed simultaneously with the related film layers of the array substrate 100 located outside the bonding region A of the flexible base substrate 11 to avoid increasing steps of manufacturing the insulating support parts 12.

For example, the array substrate further includes at least one insulating layer disposed in a display area of the flexible base substrate. At least one part of the insulating support part may be formed in same layer(s) as the at least one insulating layer in the display area to simplify the manufacturing process.

Herein, the description “formed in a same layer” in some embodiments of the present disclosure refers to performing a patterning process on a same film layer (which may be a single film or a plurality of films) made of a same material to simultaneously form different patterns. The different patterns refer to “at least one part of the insulating support part” and “at least one insulating layer in the display area” in some embodiments of the present disclosure. The description “in a same layer” means that different patterns are obtained after performing a patterning process on the same film layer. In this way, compared with a manner that different patterning processes are used for different patterns, in the manufacturing process of the array substrate provided by some embodiments of the present disclosure, by adjusting the pattern of a mask used in the patterning process, different patterns may be formed in a single patterning process, thereby simplifying the manufacturing process of the array substrate.

It will be noted that different patterns obtained by performing a patterning process on the same film layer may be located on a surface of a base, or different patterns may be located on surfaces of different bases, which may be flexibly adjusted according to the corresponding design requirements of the array substrate. Some embodiments of the present disclosure are not limited thereto.

For example, the insulating support part includes a multilayer structure.

The multilayer structure includes at least two sub-layers, and orthographic projections of the at least two sub-layers on the base substrate at least partially overlap to form a stacked structure.

A shape of each sub-layer may be the same to simplify the patterning process during manufacturing the sub-layers.

As known to those skilled in the art, the at least one insulating layer disposed in the display area of the base substrate may include a planarization layer body, a pixel defining pattern and a spacer pattern, all of which are sequentially arranged on the base substrate in a direction perpendicular to a surface of the base substrate facing the plurality of bonding pads.

Generally, the planarization layer body and the pixel defining pattern are organic film layers, and the spacer pattern may be an organic film layer or an inorganic film layer. In a case where the spacer pattern is an organic film layer, the organic film layer may be formed by a photosensitive material such as a photoresist.

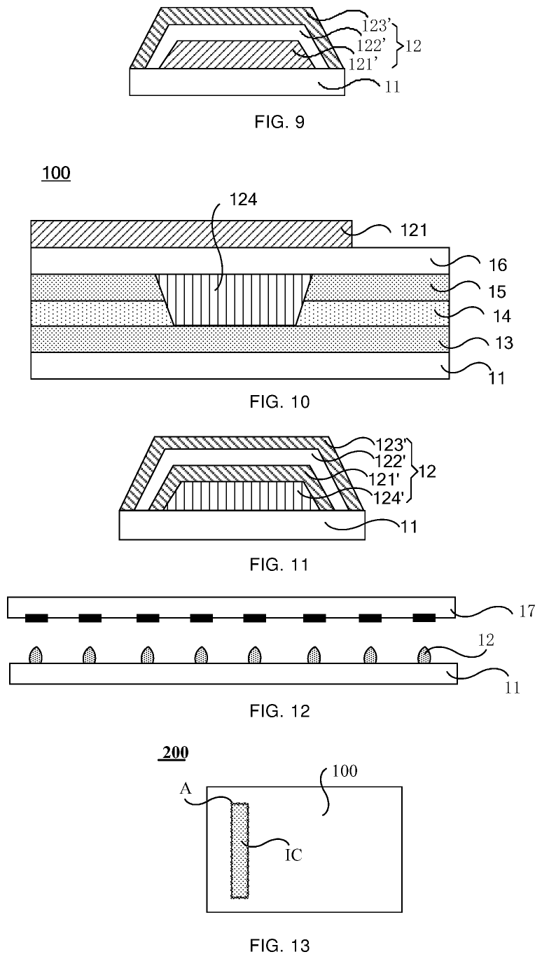

In some embodiments of the present disclosure, as shown in FIG. 9, the multilayer structure of the insulating support part 12 includes a first sub-layer (or referred to as a first pattern) 121′, a second sub-layer (or referred to as a second pattern) 122′, and a third sub-layer (or referred to as a third pattern) 123′, all of which are sequentially arranged on the base substrate 11 in a direction perpendicular to a surface of the base substrate facing the plurality of bonding pads. The first sub-layer 121′ is formed in a same layer as the planarization layer body disposed in the display area, the second sub-layer 122′ is formed in a same layer as the pixel defining pattern disposed in the display area, and the third sub-layer 123′ is formed in a same layer as the spacer pattern disposed in the display area.

Here, the first sub-layers 121′ and the planarization layer body constitute a planarization layer (referred to as a PLN layer for short), and the first sub-layer 121′ is the first pattern 121′ of the planarization layer located in the bonding region A.

The second sub-layers 122′ and the pixel defining pattern constitute a pixel defining layer (referred to as a PDL layer for short). The second sub-layer 122′ is the second pattern 122′ of the pixel defining layer located in the bonding region A.

The third sub-layers 123′ and the spacer pattern constitute a spacer layer, and the third sub-layer 123′ is the third pattern 123′ of the spacer layer (referred to as a PS layer for short) located in the bonding region A.

That is, each insulating support part 12 is composed of the first pattern 121′ of the planarization layer located in the bonding region A, the second pattern 122′ of a pixel defining layer located in the bonding region A, and the third pattern 123′ of the spacer layer located in the bonding region A, all of which are arranged in a stack.

In this case, in a case where the planarization layer, the pixel defining layer, and the spacer layer are mainly made of organic materials, a patterning process including gluing, exposing, developing, etching, etc. may be used to sequentially form the first pattern 121′ of the planarization layer located in the bonding region A, the second pattern 122′ of the pixel defining layer located in the bonding region A, and the third pattern 123′ of the spacer layer located in the bonding region A.

In a case where the spacer layer is mainly made of a photoresist material, the spacer pattern and the third pattern 123′ of the spacer layer located in the bonding region A may be formed through gluing, exposing and developing without etching, thereby simplifying the manufacturing process of the insulating support part 12.

Herein, in a case where the insulating support parts 12 are a plurality of insulating support columns spaced apart from each other, and the insulating support columns are formed through the above patterning process, a planar size of one insulating support column may be in a range from 50 μm to 100 μm.

In a case where the shape of the upper surface of the insulating support column is a rectangle, the planar size refers to a length of the rectangle; and in a case where the shape of the upper surface of the insulating support column is a circle, the planar size refers to a diameter of the circle.

In a case where the insulating support part 12 includes a first pattern 121′ of the planarization layer located in the bonding region A, a second pattern 122′ of a pixel defining layer located in the bonding region A, and a third pattern 123′ of the spacer layer located in the bonding region A, as shown in FIG. 9, the formed insulating support part 12 has a three-layer structure.

For example, an overall thickness of the insulating support part 12 with a three-layer structure is in a range of 4 μm to 8 μm.

In some embodiments of the present disclosure, for a flexible display device with bent wirings, such as a fanout flexible display device with bent wirings, wirings in the flexible display device are prone to break at a bent position. In order to avoid the above situation, as shown in FIG. 10 in general, the array substrate further includes an organic filling pattern 124 on the flexible base substrate 11 corresponding to the bent position, and the bent position is generally located between the display area and the bonding region A,

For example, the organic filling pattern 124 may be a filling layer mainly made of a polyimide (PI) material. In this case, the organic filling pattern 124 may also be referred to as a PI filling layer.

The organic filling pattern 124 is disposed between the planarization layer 121 and the flexible base substrate 11, and the organic filling pattern 124 is disposed between a source-drain metal layer 16 and the flexible base substrate 11.

For example, as shown in FIG. 10, the array substrate 100 further includes a buffer barrier layer 13, a gate insulating (GI) layer 14 and an interlayer dieletric (ILD) insulating layer 15 that are sequentially disposed on the flexible base substrate 11, and the buffer barrier layer 13 may block water vapor.

In this case, as shown in FIG. 11, the insulating support part 12 further includes a fourth sub-layer (or referred to as a fourth pattern) 124′ located at a side of the first sub-layer 121′ proximate to the base substrate 11. The fourth sub-layer 124′ is formed in a same layer as the organic filling pattern at the bent position.

Herein, the fourth sub-layers 124′ and the organic filling pattern constitute an organic filling layer, and the fourth sub-layer 124′ is a forth pattern 124′ of the organic filling layer located in the bonding region A.

In this case, the insulating support part 12 has a four-layer structure. That is, the insulating support part 12 includes: a forth pattern 124′ of the organic filling layer 124 located in the bonding region A, a first pattern 121′ of the planarization layer located in the bonding region A, a second pattern 122′ of the pixel defining layer located in the bonding region A, and a third pattern 123′ of the spacer layer located in the bonding region A, all of which are sequentially disposed on the flexible base substrate 11.

For example, an overall thickness of the insulating support part 12 with a four-layer structure is in a range of 6 μm to 10 μm.

In some other embodiments of the present disclosure, in a case where a thin film encapsulation (TFE) is used in a flexible display device formed by the array substrate 100, the array substrate 100 further includes a thin film encapsulation layer disposed on the flexible base substrate 11. The thin film encapsulation layer is able to prevent water vapor from entering an organic light-emitting material layer in the flexible display device, thereby preventing the organic light-emitting material layer from losing efficacy.

The thin film encapsulation layer generally includes two inorganic film layers and an organic film layer that is located between the two inorganic film layers. The organic film layer may be formed by an inkjet printing method.

Correspondingly, the insulating support part may include a fifth sub-layer (or referred to as a fifth pattern). The fifth sub-layer may be formed in a same layer as an organic protective film layer of the organic film layer in the thin film encapsulation layer located in an encapsulation region.

In this case, the insulating support part 12 includes a pattern of the organic film layer located in the bonding region A.

The insulating support part 12 may be formed by the inkjet printing method. In this case, the fifth sub-layer of the insulating support part 12 is formed in a same layer as the organic protective film layer in the encapsulation region.

As shown in FIG. 12, when the organic protective film layer is formed by using the inkjet printing method, the insulating support part 12 may be printed in the bonding region A of the flexible base substrate 11 at the same time by controlling a position and printing time of a print head 17.

Herein, a density of the insulating support parts 12 to be formed may be adjusted according to a size of the insulating support part 12. For example, in a case where the material used for printing the insulating support parts 12 has a good fluidity, the planar size of the insulating support part 12 formed by printing is large, and in this case, a density of the printed insulating support parts 12 needs to be reduced; in a case where the material used for printing the insulating support part 12 has a poor fluidity, the planar size of the insulating support part 12 formed by printing is small, and in this case, and a density of the printed insulating support parts 12 may be increased.

After the printing is completed, the insulating support parts 12 may be cured by using ultraviolet light to enhance their stability.

For example, the insulating support parts 12 are a plurality of insulating support columns spaced apart from each other, and a planar size of each insulating support column formed by the inkjet printing method is in a range from 50 μm to 200 μm, and a thickness thereof is in a range from 5 μm to 10 μm.

In a case where the shape of the upper surface of the insulating support column is a rectangle, the planar size refers to a length or width of the rectangle; and in a case where the shape of the upper surface of the insulating support column is a circle, the planar size refers to a diameter of the circle.

The fifth sub-layer of the insulating support parts 12 may be formed in a same layer as the organic protective film layer in the thin film encapsulation layer through the printing process.

In another aspect, some embodiments of the present disclosure provide a display device (e.g., a flexible display device) 200. As shown in FIG. 13, the flexible display device includes any one of the array substrates 100 as described above and an IC (marked as “IC” in FIG. 13). The IC includes IC bumps, and the IC bumps are bonded to the array substrate 100 through the bonding pads of the array substrate.

Herein, please refer to FIG. 4 for the IC bumps, which are not described herein again.

The flexible display device includes an array substrate having the same structure and beneficial effects as the array substrate provided by the above embodiments. Since the beneficial effects of the array substrate have been described in detail in the above embodiments, details are not described herein again.

For example, the flexible display device may be an organic light-emitting diode (OLEO) flexible display panel including the above array substrate, or may be an OLEO display device including the above array substrate.

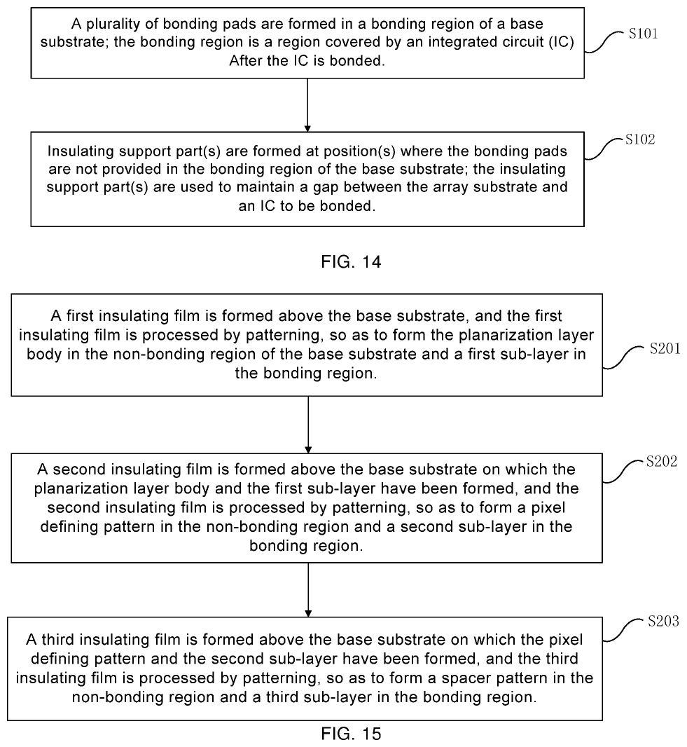

In yet another aspect, some embodiments of the present disclosure provide a manufacturing method of the array substrate 100, and as shown in FIG. 14, the manufacturing method includes step 101 (S101) to step 102 (S102).

In S101, a plurality of bonding pads 10 are formed in a bonding region of a base substrate 11. The bonding pads 10 are used to bond IC bumps 42, and the bonding region is a region covered by an IC after the IC is bonded.

In S102, insulating support parts 12 are formed at positions where the bonding pads are not provided in the bonding region A of the base substrate 11. The insulating support parts 12 are used to maintain a gap between the array substrate and an IC to be bonded.

Herein, the S101 and S102 may be performed simultaneously; or, the S101 may be performed first and then the S102 may be performed; or, the S102 may be performed first and then the S101 may be performed.

In some embodiments of the present disclosure, as shown in FIG. 4, a distance from an upper surface 12a of the insulating support part 12 facing away from the base substrate 11 to a surface of the base substrate 11 facing the plurality of bonding pads is greater than a distance from an upper surface 10a of the bonding pad 10 facing away from the base substrate 11 to a surface of the base substrate 11 facing the plurality of bonding pads.

That is, the upper surface of the insulating support part 12 facing away from the flexible base substrate 11 is higher than a plane where the upper surface of the bonding pad 10 facing away from the flexible base substrate 11 is located. A portion of the insulating support part 12 that is higher than the bonding pad may further provide a support force to the IC.

In some embodiments of the present disclosure, in a direction perpendicular to a surface of the flexible base substrate 11, a height of the insulating support part 12 is as high as possible without affecting the bonding between the IC and the bonding pads to provide a more firm support for the IC.

That is, as shown in FIG. 4, in the direction perpendicular to the surface of the base substrate 11, a difference between the distance from the upper surface 12a of the insulating support part 12 to the surface of the base substrate 11 facing the plurality of bonding pads and the distance from the upper surface 10a of the bonding pad 10 to the surface of the base substrate 11 facing the plurality of bonding pads is less than or equal to a thickness of an IC bump of the IC to be bonded.

Herein, the height of the insulating support part 12 may be adjusted according to the type of the IC.

For example, in a case where a structure of the IC is as shown in FIG. 4, in an example where the lower surfaces of the IC bumps 42 and the upper surface of the IC body 41 are in a same plane, in order not to affect the bonding between the IC and the bonding pads, a height H from the upper surface of the insulating support part 12 to a plane where the upper surface 10a of the bonding pad is located is less than or equal to a thickness h of the IC bump 42. In this way, in a case where the IC bumps 42 are bonded to the bonding pads 10, it may be ensured that a middle portion of the IC body 41 will not be lifted up by the insulating support part 12, thereby not affecting the bonding effect of the IC.

In the array substrate provided by some embodiments of the present disclosure, the insulating support parts 12 may be manufactured separately. That is, a step of manufacturing the insulating support parts 12 is added on the basis of steps of manufacturing the related array substrate. Or, the insulating support part may also be manufactured simultaneously with one or more layers in a structure of the array substrate outside the bonding region A of the flexible substrate. That is, the insulating support parts 12 may be manufactured by changing pattern(s) of one or more layers in the related array substrate, thereby not increasing the steps of manufacturing the array substrate.

Herein, in order to simplify the manufacturing of the insulating support parts 12, the insulating support parts 12 may be formed in a same layer as some structures in the display area.

That is, the manufacturing method further includes forming at least one insulating layer in the display area of the base substrate. At least one part of the insulating support part is formed in a same layer as the at least one insulating layer in the display area.

Herein, the description “formed in a same layer” in some embodiments of the present disclosure refers to performing a patterning process on a same film layer (which may be a single film or a plurality of films) made of a same material to simultaneously form different patterns. The different patterns refer to “at least one part of the insulating support part” and “at least one insulating layer in the display area” in some embodiments of the present disclosure. The description “in a same layer” means that different patterns are obtained after performing a patterning process on the same film layer. In this way, compared with a manner that different patterning processes are used for different patterns, in the manufacturing process of the array substrate provided by some embodiments of the present disclosure, by adjusting the pattern of a mask used in the patterning process, different patterns may form in a single patterning process, thereby simplifying the manufacturing process of the array substrate.

It will be noted that different patterns obtained by performing a patterning process on the same film layer may be located on a surface of a base, or different patterns may be located on different surfaces of different bases, which may be flexibly adjusted according to the corresponding design requirements of the array substrate. Some embodiments of the present disclosure are not limited thereto.

In an example where the formed insulating support part includes a multilayer structure, some exemplary manufacturing processes are provided in the following to describe a process of manufacturing the insulating support part in detail.

A planarization layer body, a pixel defining pattern, and a spacer pattern, which are sequentially disposed above the base substrate in a direction perpendicular to a surface of the base substrate facing the plurality of bonding pads, are formed in the display area of the base substrate. Forming the insulating support part includes: forming a first sub-layer, a second sub-layer, and a third sub-layer, all of which are sequentially disposed above the base substrate in the direction perpendicular to the surface of the base substrate facing the plurality of bonding pads. The first sub-layer is formed in a same layer as the planarization layer body, the second sub-layer is formed in a same layer as the pixel defining pattern, and the third sub-layer is formed in a same layer as the spacer pattern.

For example, a method of forming the insulating support part 12 includes step 201 (S201) to step 203 (S203) as shown in FIG. 15.

In S201, a first insulating film is formed above the flexible base substrate 11, and the first insulating film is processed by patterning, so as to form a planarization layer body in the display area of the flexible base substrate 11 and a first sub-layer 121′ in the bonding region A of the flexible base substrate 11.

The first sub-layers 121′ and the planarization layer body constitute a planarization layer, and the first sub-layer 121′ is a pattern of the planarization layer 121 located in the bonding region.

Patterning in some embodiments of the present disclosure refers to a patterning process, which may include a photolithography process, or include a process such as a photolithography process and an etching step to form a predetermined pattern. The photolithography process includes film formation, exposing, developing, etc.

For example, the photolithography process in some embodiments of the present disclosure refers to a process of forming a pattern by using a photoresist, a mask, an exposure machine, and the like.

In some embodiments of the present disclosure, the equipment and process for forming the first sub-layer is compatible with the equipment for manufacturing the related array substrate. For example, by controlling a shape of the mask, exposing and developing the photoresist, and etching a film layer exposed by the photoresist, the first sub-layer may be formed in the bonding region A of the flexible base substrate 11.

It should be understood by those skilled in the art that, before the planarization layer 121 is formed on the flexible base substrate 11, manufacturing the array substrate also includes forming a gate, a gate insulating layer, an active layer, a source-drain metal layer, etc. on the flexible base substrate 11. The processes of forming the film layers are the same as the related manufacturing processes, which will not be described herein again.

In S202, a second insulating film is formed above the flexible base substrate 11 on which the planarization layer body and the first sub-layer 121′ have been formed, and the second insulating film is processed by patterning, so as to form a pixel defining pattern in the display area and a second sub-layer 122′ in the bonding region A.

The second sub-layers 122′ and the pixel defining pattern constitute a pixel defining layer, and the second sub-layer 122′ is a pattern of the pixel defining layer located in the bonding region.

Herein, the pixel defining pattern in the display area is generally in a shape of a mesh to define a plurality of sub-pixel regions.

In S203, a third insulating film is formed above the flexible base substrate 11 on which the pixel defining pattern and the second sub-layer have been formed, and the third insulating film is processed by patterning, so as to form a spacer pattern in the display area and a third sub-layer in the bonding region A.

The third sub-layers and the spacer pattern constitute a spacer layer, and the third sub-layer is a pattern of the spacer layer located in the bonding region,

That is, the formed insulating support part 12 includes the first sub-layer, the second sub-layer, and the third sub-layer.

In this way, the formed insulating support part 12 has a three-layer structure. The insulating support part 12 may be formed simultaneously with the related film layers in the array substrate, and thus there is no need to manufacture the insulating support part 12 separately, which simplifies the process of forming the array substrate including the insulating support parts 12.

In addition, in a display device with bent wirings, such as a fanout flexible display device with bent wirings, wirings on the flexible display device are prone to break at a bent position. In order to avoid the above situation, generally as shown in FIG. 10, the array substrate further includes an organic filling layer 124 at a position corresponding to the bent position on the flexible base substrate 11, and the organic filling layer 124 is further disposed between a source-drain metal layer 16 and the flexible base substrate 11. Generally, the bent position is located between the display area and the bonding region A.

In this way, before the planarization layer 121 is formed, the manufacturing method further includes:

forming a fourth insulating film above the flexible base substrate 11 and performing a patterning process on the fourth insulating film to form an organic filling pattern in a region between the display area and the bonding region A, and a fourth sub-layer in the bonding region A of the flexible base substrate 11.

The fourth sub-layers and the organic filling pattern constitute an organic filling layer 124, and the fourth sub-layer is a pattern of the organic filling layer 124 located in the bonding region.

In this case, the insulating support part 12 further includes the fourth sub-layer.

Herein, for the flexible display device with bent wirings, during manufacturing the array substrate, for example, a pre-bent region is determined first, and then a shape of the mask is controlled according to the pre-bent region. During patterning the fourth insulating film, the fourth insulating film is exposed by using the mask. An organic filling pattern may be formed at a position corresponding to the bent position between the display area of the flexible base substrate 11 and the bonding region A of the flexible base substrate 11, and the fourth sub-layer is simultaneously formed in the bonding region A.

In this case, the formed insulating support part 12 has a four-layer structure.

Compared with the insulating support part 12 with a three-layer structure, the insulating support part 12 with a four-layer structure may appropriately increase the height of the insulating support part 12 to further reduce a distance between the upper surface of the insulating support part 12 and the IC body 41 during bonding the IC. In this way, the surface of the flexible base substrate 11 may be flatter after the IC is bonded, and the risk of wire breakages of the flexible base substrate 11 and aggregation of conductive particles on the flexible base substrate 11 may be reduced. Moreover, a risk of short circuits caused by contact between wirings on the flexible base substrate 11 and the circuit traces on the IC body 41 may be further avoided.

In some other embodiments of the present disclosure, the manufacturing method further includes: forming at least one insulating layer in an encapsulation region of the base substrate. At least one part of the insulating support part is formed in a same layer as the at least one insulating layer in the encapsulation region.

For example, the at least one insulating layer includes an organic protective film layer. Forming the insulating support part includes forming a fifth sub-layer, which is formed in a same layer as the organic protective film layer.

The fifth sub-layer included in the insulating support part 12 may be formed by using the inkjet printing method. The following example is for illustration.

An organic protective film layer in the encapsulation region of the flexible base substrate 11 and a fifth sub-layer in the bonding region A of the flexible base substrate 11 are formed on the flexible base substrate 11 by using the inkjet printing method.

As known to those skilled in the art, before the thin film encapsulation layer is formed, the manufacturing method of the array substrate further includes steps of forming layer structures required for display on the flexible base substrate 11, such as steps of forming a gate, a source, a drain, and a light-emitting layer. The steps for forming the layer structures are the same as the manufacturing process of the related array substrate, which will not be described herein again. In addition, the thin film encapsulation layer generally includes two inorganic film layers and an organic film layer that is located between the two inorganic film layers, and the organic film layer may be formed by using the inkjet printing method.

Herein, the fifth sub-layers and the organic protective film layer constitute an organic film layer, and the organic film layer is an organic film layer in a thin film encapsulation layer. In this case, the insulating support part 12 includes a fifth sub-layer.

For example, as shown in FIG. 12, when the organic film layer is formed by using the inkjet printing method, the insulating support parts 12 are simultaneously printed in the bonding region A of the flexible base substrate 11 by controlling a position and printing time of the print head 17, and then the insulating support parts 12 may be cured by ultraviolet curing.

Since the array substrate further includes the insulating support parts 12 that are located at positions where the bonding pads are not provided in the bonding region A of the flexible base substrate 11, and the upper surface of the insulating support part 12 is higher than the plane where the upper surface of the bonding pad 10 is located, the insulating support part 12 may play a certain supporting role, so that a fixed distance is maintained between the IC and the peripheries of the regions of the flexible base substrate 11 corresponding to the IC bumps 42. As a result, the wirings on the warped portion of the flexible base substrate 11 are prevented from being in contact with the circuit traces on the IC, thereby reducing the risk of short circuits.

In addition, since the insulating support parts 12 may maintain a fixed distance between the IC and the peripheries of the regions of the flexible base substrate 11 corresponding to the IC bumps 42, the segment difference between the region of the flexible base substrate 11 corresponding to the IC bumps 42 and the periphery thereof may be reduced. In this way, after the IC bonding process is completed, the surface of the flexible base substrate 11 is flat. As a result, in one aspect, the probability of wire breakages of the flexible base substrate 11 may be reduced; in another aspect, the probability of aggregation of conductive particles occurring at positions corresponding to the IC bumps 42 may be reduced, thereby reducing the risk of short circuits caused by the aggregation of the conductive particles.

In yet another aspect, some embodiments of the present disclosure provide a manufacturing method of a display device. The display device, for example, may be a flexible display device. The manufacturing method of the flexible display device includes the following steps.

An array substrate is formed on a rigid support substrate (e.g., a glass substrate) by using the manufacturing method of the array substrate provided in any one of the above embodiments. The base substrate in the array substrate is a flexible base substrate; the rigid support substrate provides a stable support for the flexible base substrate, and corresponding structures on the flexible base substrate are formed.

The array substrate is peeled from the rigid support substrate.

A protective back film is attached on a side of the flexible base substrate away from the bonding pads and the insulating support parts to flatten the peeled flexible base substrate.

An IC is provided which includes IC bumps. The IC bumps are bonded to the bonding pads.

Herein, in a case where the formed flexible array substrate is a mother board including a plurality of sub-array substrates, the manufacturing method may further include a process of cutting the peeled mother board before the IC is bonded.

The manufacturing method of the flexible display device includes any one of the manufacturing methods of the array substrate as described above, and has the same steps and beneficial effects as the manufacturing method of the array substrate provided by the foregoing embodiments. Since the steps and the beneficial effects of the manufacturing method of the array substrate have been described in detail in the above embodiments, they will not be described herein again.

The forgoing descriptions are merely specific implementation manners of the present disclosure, but the protection scope of the present disclosure is not limited thereto. Any person skilled in the art could readily conceive of changes or replacements within the technical scope of the present disclosure, which shall all be included in the protection scope of the present disclosure. Therefore, the protection scope of the present disclosure shall be subject to the protection scope of the claims.

1. A manufacturing method of an array substrate, the manufacturing method comprising:
forming a plurality of bonding pads in a bonding region of a base substrate, and
forming at least one insulating support part at at least one position where the plurality of bonding pads are not provided in the bonding region of the base substrate.

2. The manufacturing method according to claim 1, wherein a distance from a surface of the at least one insulating support part facing away from the base substrate to a surface of the base substrate facing the plurality of bonding pads is greater than a distance from a surface of at least one bonding pad facing away from the base substrate to the surface of the base substrate facing the plurality of bonding pads.

3. (canceled)

4. The manufacturing method according to claim 1, wherein the manufacturing method further comprises: forming at least one insulating layer in a non-bonding region of the base substrate; and
at least one part of an insulating support part is formed in a same layer as an insulating layer.

5. (canceled)

6. The manufacturing method according to claim 4, wherein forming at least one insulating layer in the non-bonding region of the base substrate, includes: sequentially forming a planarization layer body, a pixel defining pattern and a spacer pattern in the non-bonding region of the base substrate in a direction perpendicular to a surface of the base substrate facing the plurality of bonding pads,
forming one of the at least one insulating support part, includes: sequentially forming a first sub-layer, a second sub-layer and a third sub-layer in the direction perpendicular to the surface of the base substrate facing the plurality of bonding pads, wherein
the first sub-layer is formed in a same layer as the planarization layer body;
the second sub-layer is formed in a same layer as the pixel defining pattern; and
the third sub-layer is formed in a same layer as the spacer pattern.

7. The manufacturing method according to claim 6, wherein forming the at least one insulating layer and forming one of the at least one insulating support part, includes:
forming a first insulating film above the base substrate, and performing a patterning process on the first insulating film to form the planarization layer body in the non-bonding region of the base substrate and the first sub-layer in the bonding region;
forming a second insulating film above the base substrate above which the planarization layer body and the first sub-layer have been formed, and performing a patterning process on the second insulating film to form the pixel defining pattern in the non-bonding region and the second sub-layer in the bonding region; and
forming a third insulating film above the base substrate above which the pixel defining pattern and the second sub-layer have been formed, and performing a patterning process on the third insulating film to form the spacer pattern in the non-bonding region and the third sub-layer in the bonding region.

8. The manufacturing method according to claim 6, further comprising:
forming an organic filling pattern in a region between the non-bonding region of the base substrate and the bonding region of the base substrate before forming the planarization layer body, wherein
forming the one of the at least one insulating support part further includes: forming a fourth sub-layer before forming the first sub-layer, wherein the fourth sub-layer is formed in a same layer as the organic filling pattern.

9. The manufacturing method according to claim 8, wherein forming the at least one insulating layer and forming one of the at least one insulating support part, includes:
forming a forth insulating film above the base substrate, and performing a patterning process on the forth insulating film to form the organic filling pattern in the region between the non-bonding region of the base substrate and the bonding region of the base substrate and the forth sub-layer in the bonding region;
forming a first insulating film above the base substrate above which the organic filling pattern and the forth sub-layer have been formed, and performing a patterning process on the first insulating film to form the planarization layer body in the non-bonding region of the base substrate and the first sub-layer in the bonding region;
forming a second insulating film above the base substrate above which the planarization layer body and the first sub-layer have been formed, and performing a patterning process on the second insulating film to form the pixel defining pattern in the non-bonding region and the second sub-layer in the bonding region; and
forming a third insulating film above the base substrate above which the pixel defining pattern and the second sub-layer have been formed, and performing a patterning process on the third insulating film to form the spacer pattern in the non-bonding region and the third sub-layer in the bonding region.

10.-15. (Canceled)

16. A manufacturing method of a display device, comprising:
forming an array substrate on a rigid support substrate by the manufacturing method according to claim 1, wherein the base substrate in the array substrate is a flexible base substrate;
peeling the array substrate from the rigid support substrate;
attaching a protective back film on a side of the flexible substrate facing away from the plurality of bonding pads;
providing at least one IC, wherein each IC includes a plurality of IC bumps; and bonding each IC bump to a corresponding bonding pad.

17. An array substrate, comprising:
a base substrate having a bonding region,
a plurality of bonding pads disposed in the bonding region, and
at least one insulating support part disposed at at least one position where the plurality of bonding pads are not provided in the bonding region.

18. The array substrate according to claim 17, wherein a distance from a surface of the at least one insulating support part facing away from the base substrate to a surface of the base substrate facing the plurality of bonding pads is greater than a distance from a surface of at least one bonding pad facing away from the base substrate to the surface of the base substrate facing the plurality of bonding pads.

19. (canceled)

20. The array substrate according to claim 17, wherein the plurality of bonding pads include a first bonding pad group and a second bonding pad group, and the at least one insulating support part includes at least one insulating support part group, wherein
the first bonding pad group includes at least one input bonding pad, and the second bonding pad group includes at least one output bonding pad, and
the first bonding pad group, the second bonding pad group and the at least one insulating support part group are spaced apart from each other.

21. The array substrate according to claim 20, wherein at least one insulating support part group includes a plurality of insulating support part groups,
one or more insulating support part groups are disposed at a side of the first bonding pad group facing away from the second bonding pad group, or
one or more insulating support part groups are disposed at a side of the second bonding pad group facing away from the first bonding pad group, or
one or more insulating support part groups are disposed at the side of the first bonding pad group facing away from the second bonding pad group, and one or more insulating support part groups are disposed at the side of the second bonding pad group facing away from the first bonding pad group.

22. (canceled)

23. The array substrate according to claim 20, wherein
the first bonding pad group includes at least one row of input bonding pads spaced apart from each other, the second bonding pad group includes at least one row of output bonding pads spaced apart from each other, and the at least one insulating support part group includes at least one row of insulating support parts spaced apart from each other; and
the at least one row of input bonding pads, the at least one row of output bonding pads and the at least one row of insulating support parts are parallel to each other.

24.-25. (canceled)

26. The array substrate according to claim 17, wherein an area of a surface of an insulating support part facing away from the base substrate is less than an area of a surface of the insulating support part facing the base substrate.

27. The array substrate according to claim 17, further comprising at least one insulating layer disposed in a non-bonding region of the base substrate; and
at least one part of an insulating support part is formed in a same layer as an insulating layer.

28. (canceled)

29. The array substrate according to claim 27, wherein the at least one insulating layer includes a planarization layer body, a pixel defining pattern and a spacer pattern, all of which are sequentially disposed above the base substrate in a direction perpendicular to a surface of the base substrate facing the plurality of bonding pads;
one of the at least one insulating support part includes a first sub-layer, a second sub-layer and a third sub-layer, all of which are sequentially disposed above the base substrate in the direction perpendicular to the surface of the base substrate facing the plurality of bonding pads, wherein
the first sub-layer is disposed in a same layer as the planarization layer body;
the second sub-layer is disposed in a same layer as the pixel defining pattern; and
the third sub-layer is disposed in a same layer as the spacer pattern.

30. The array substrate according to claim 29, further comprising an organic filling pattern disposed between the planarization layer and the base substrate and located in a region between the non-bonding region and the bonding region, wherein
the insulating support part further includes a fourth sub-layer located between the first sub-layer and the base substrate, wherein the fourth sub-layer is formed in a same layer as the organic filling pattern.

31.-32. (canceled)

33. A display device, comprising:
the array substrate according to claim 17; and
at least one IC, wherein
each IC includes a plurality of IC bumps, and each IC bump is bonded to a corresponding bonding pad.

34. The array substrate according to claim 20, wherein the at least one insulating support part group is disposed between the first bonding pad group and the second bonding pad group.

35. The display device according to claim 33, wherein a difference between a distance from a surface of the at least one insulating support part facing away from the base substrate to a surface of the base substrate facing the plurality of bonding pads and a distance from a surface of at least one bonding pad facing away from the base substrate to the surface of the base substrate facing the plurality of bonding pads is less than or equal to a thickness of at least one IC bump.
